(19) United States
(12) Patent Application Publication
(10) Pub. No.: US 2007/0158705 A1
(43) Pub. Date: Jul. 12, 2007

(54) SEMICONDUCTOR DEVICE

(76) Inventor: Mariko Takayanagi, Kawasaki-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/619,785

(22) Filed: Jan. 4, 2007

(30) Foreign Application Priority Data
Jan. 11, 2006 (JP) 2006-003985

(51) Int. Cl. H01L 29/76

(52) U.S. Cl. 257/288

(57) ABSTRACT

A semiconductor device including a semiconductor substrate having at least one pair of a source region and a drain region being formed at a surface layer portion thereof, a gate insulating film being provided on a surface of the semiconductor substrate between the source region and the drain region and having a relative dielectric constant of 5 or more, and a gate electrode being provided on a surface of the gate insulating film and made of a polycrystalline silicon based material containing at least one type of impurity, wherein a substance which restricts movement of the impurity from the polycrystalline silicon based material to the gate insulating film is provided in a vicinity of an interface to the gate insulating film.

### CROSS-REFERENCE TO RELATED APPLICATIONS

This application is based upon and claims the benefit of priority from prior Japanese Patent Application No. 2006-003985, filed Jan. 11, 2006, the entire contents of which are incorporated herein by reference.

### BACKGROUND OF THE INVENTION

1. Field of the Invention

The present invention relates to a semiconductor device which comprises an MIS transistor. In particular, the present invention relates to a semiconductor device which comprises an MOS transistor featured in that a gate electrode is made of a polysilicon based material and a gate insulating film is made of a metal oxide based high relative dielectric constant insulating film.

2. Description of the Related Art

A transistor having a structure in which an insulating layer serving as a gate insulating film and a conductive layer serving as a gate electrode are stacked on a semiconductor substrate is generally referred to as a metal insulator semiconductor (MIS). Among these MIS transistors, a transistor whose insulating layer is formed of an oxide based material is called a metal oxide semiconductor (MOS) transistor, in particular. In this MOS transistor, it is known that there occurs a phenomenon referred to as a so called flat band shift in which a flat band voltage is shifted.

For example, in a CMOSFET which is one type of MOS transistor, a gate insulating film is formed by using a so called high relative dielectric constant insulating film (high-k film) made of HfO₂, HfSiO, HfSiON and the like. In addition, a gate electrode is formed of a polysilicon (polycrystalline silicon) based material such as poly-Si or poly-SiGe. Then, a flat band voltage is further greatly shifted by several hundreds mV as compared with a case in which a gate insulating film is formed of SiO₂ which is a general insulator. Such a phenomenon is disclosed in “A. Kaneko et al., Ext. Abst. of SSDM, p. 56 (2003)” and “M. Takayanagi, IWGI 2003 (2003)”, for example. If this flat band shift increases, it becomes difficult to control a threshold voltage of the CMOSFET. Further, it becomes difficult to stably actuate a whole semiconductor device comprising such a transistor, and there is a high danger that its reliability, performance, quality or the like are degraded.

### BRIEF SUMMARY OF THE INVENTION

According to an aspect of the invention, there is provided a semiconductor device comprising: a semiconductor substrate having at least one pair of a source region and a drain region being formed at a surface layer portion thereof; a gate insulating film being provided on a surface of the semiconductor substrate between the source region and the drain region and having a relative dielectric constant of 5 or more; and a gate electrode being provided on a surface of the gate insulating film and made of a polycrystalline silicon based material containing at least one type of impurity, wherein a substance which restricts movement of the impurity from the polycrystalline silicon based material to the gate insulating film is provided in a vicinity of an interface to the gate insulating film.

According to another aspect of the invention, there is provided a semiconductor device comprising: a semiconductor substrate having at least one pair of a source region and a drain region being formed at a surface layer portion thereof; a gate insulating film being provided on a surface of the semiconductor substrate between the source region and the drain region and having a relative dielectric constant of 5 or more; and a gate electrode being provided on a surface of the gate insulating film and made of a polycrystalline silicon based material containing at least one type of impurity, wherein at least one of carbon (C), nitrogen (N), and oxygen (O) is maldistributed in a vicinity of an interface to the gate insulating film.

According to still another aspect of the invention, there is provided a semiconductor device comprising: a semiconductor substrate having at least one pair of a source region and a drain region being formed at a surface layer portion thereof; a gate insulating film being provided on a surface of the semiconductor substrate between the source region and the drain region and having a relative dielectric constant of 5 or more; and a gate electrode being provided on a surface of the gate insulating film and made of a polycrystalline silicon based material containing at least one type of impurity, wherein at least one of aluminum (Al), titanium (Ti), tungsten (W), tantalum (Ta), and ruthenium (Ru) is maldistributed in a vicinity to the gate insulating film.

### BRIEF DESCRIPTION OF THE SEVERAL VIEWS OF THE DRAWING

FIG. 1 is a process sectional view showing a process for manufacturing a semiconductor device according to a first embodiment;

FIG. 2 is a process sectional view showing a process for manufacturing the semiconductor device according to the first embodiment;

FIG. 3 is a process sectional view showing a process for manufacturing the semiconductor device according to the first embodiment;

FIG. 4 is an enlarged view showing the vicinity of a gate electrode of MOSFET which the semiconductor device shown in FIG. 3 comprises;

FIG. 5 is a view showing, along a film thickness direction of a gate electrode, a concentration profile in the vicinity of the gate electrode of a substance which restricts movement of impurities, contained in the gate electrode shown in FIG. 4, to a gate insulating film;

FIG. 6 is a graphical diagram depicting capacitor characteristics of each one of MOSFET according to the first embodiment and MOSFET according to a modified example thereof and capacitor characteristics of MOSFET according to Comparative Example relevant thereto by implanted impurities in the gate electrode and by types of gate insulating films; and

FIG. 7 is a graphical diagram depicting capacitor characteristics of MOSFET according to Comparative Example relevant to the first embodiment by implanted impurities in the gate electrode and by types of gate insulating films.

### DETAILED DESCRIPTION OF THE INVENTION

Hereinafter, embodiments of the present invention will be described with reference to the accompanying drawings.

### First Embodiment

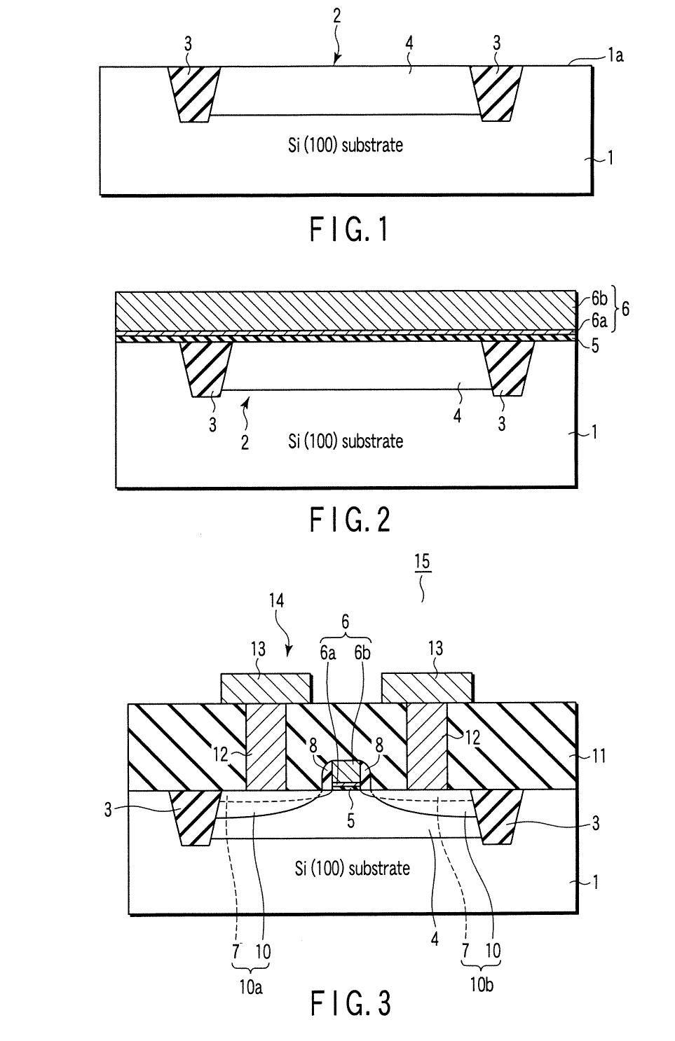

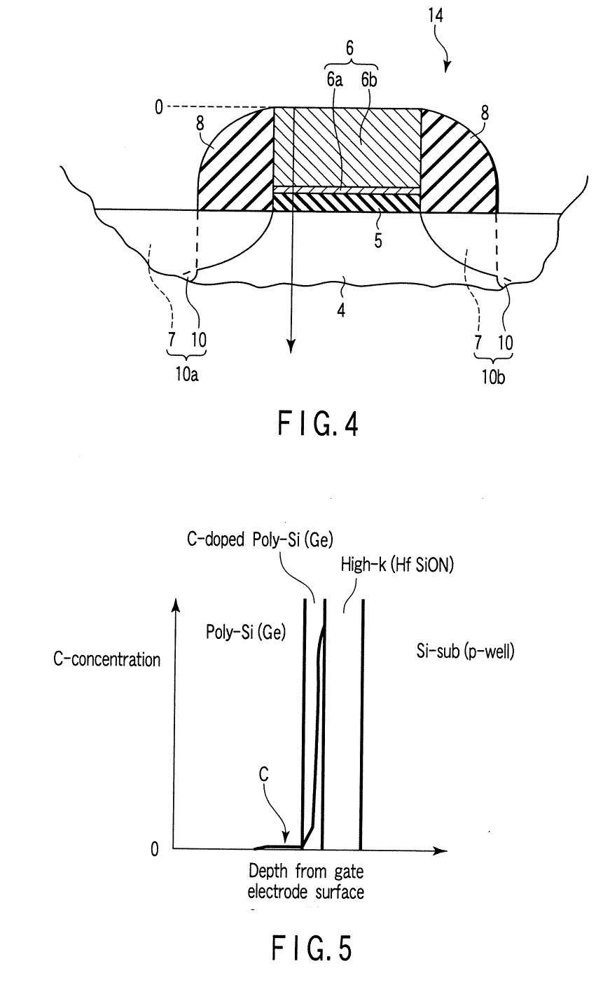

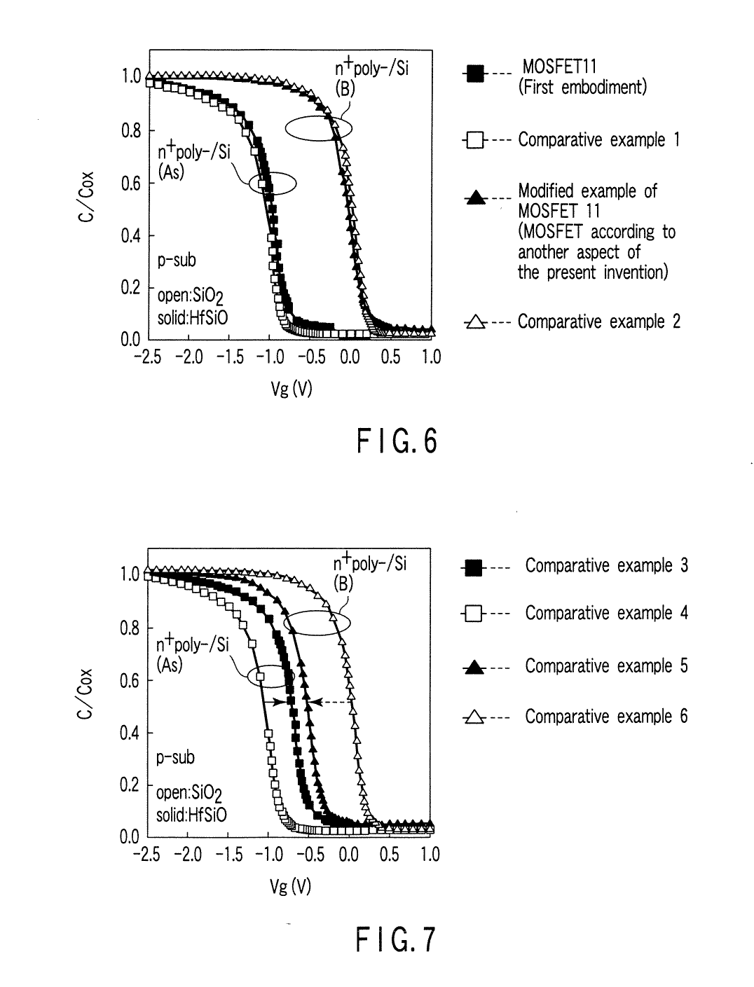

First, a first embodiment according to the present invention will be described with reference to FIGS. 1 to 7. FIGS. 1 to 3 are process sectional views each showing a process for manufacturing a semiconductor device according to the present embodiment. FIG. 4 is an enlarged view showing the vicinity of a gate electrode of MOSFET which the semiconductor device shown in FIG. 3 comprises. FIG. 5 is a view showing, along a film thickness direction of a gate electrode, a concentration profile in the vicinity of the gate electrode of a substance which restricts movement of impurities, contained in the gate electrode shown in FIG. 4, to a gate insulating film. FIG. 6 is a graphical diagram depicting capacitor characteristics of each one of MOSFET according to the present embodiment and MOSFET according to a modified example thereof and capacitor characteristics of MOSFET according to Comparative Example relevant thereto by implanted impurities in the gate electrode and by types of gate insulating films. FIG. 7 is a graphical diagram depicting capacitor characteristics of MOSFET according to Comparative Example relevant to the present embodiment by implanted impurities in the gate electrode and by types of gate insulating films.

In the present embodiment, a description will be given with respect to a technique of restricting a flat band shift of MOSFET featured in that a gate insulating film is formed of a so called high relative dielectric constant insulating film and a gate electrode is formed of a polycrystalline silicon based material. Specifically, a description will be given with respect to a technique of restricting a flat band shift by introducing a substance, which restricts at least impurities contained in a gate electrode from dispersing into a gate insulating film, into the vicinity of an interface between the gate electrode and the gate insulating film in the MOSFET made of the previously described structure.

First, as shown in FIG. 1, a Shallow Trench Isolation (STI) structure is provided at a surface layer portion of an n-type silicon wafer 1 serving as a semiconductor substrate. Specifically, among the surface layer portions of the silicon wafer 1, a transistor forming region 2 in which MOSFET 14 is provided is surrounded by oxide films 3 made of SiO₂ or the like that is an insulating material are embedded at the outside of the transistor forming region 2. In this manner, STIs (embedded oxide films) 3 are formed at the surface layer portion of the silicon wafer 1, and an element region (transistor forming region) 2 surrounded by the STIs 3 is electrically isolated from another element region. A (100) face of a silicon crystal is defined as a main face (surface) 1a on which STI 3 of the silicon wafer 1 is to be formed. In the following description, the silicon wafer 1 is referred to as a Si (100) substrate 1.

Although not shown, a SiO₂ film independent of STI 3 is newly provided on a surface 1a of the Si (100) substrate 1 on which each STI 3 has been formed. At this time, the SiO₂ film newly provided is deposited (formed) on the surface 1a of the Si (100) substrate 1 in accordance with a CVD technique so that its film thickness is formed in the shape of thin film having about 10 nm. Then, by using this thin film shaped SiO₂ film as a sacrificed oxide film, p-type impurities (dopant) are selectively introduced into a predetermined region of the surface layer portion of the Si (100) substrate 1. Specifically, among the transistor forming region 2, for example, boron (B) or indium (In) and the like is implanted in accordance with an ion implantation technique (ion implanting technique) into a well 4 and a region serving as a channel described later. Then, through a predetermined process such as anneal processing, a well (p-well) 4 containing p-type impurities and a channel region which is not shown are formed in the transistor forming region 2. Then, by using dilute fluorinated acid, the sacrificed oxide film made of a SiO₂ film is removed by releasing it from the surface 1a of the Si (100) substrate 1.

Next, as shown in FIG. 2, a so called high relative dielectric constant insulating film (high-k film) 5 that is an insulating film having a relative dielectric constant of 5 or more is provided by covering the surface 1a of the Si (100) substrate 1 on which the p-well 4 has been formed. This high relative dielectric constant insulating film 5 is provided as a gate insulating film described later. In the present embodiment, a film (metal oxide film) made of oxide of hafnium (Hf) that is a metal element of the IV-A group is provided as the high relative dielectric constant insulating film 5. Specifically, by using an MOCVD technique and a plasma nitriding technique, an HfSiON film 5 is formed on the surface 1a of the Si (100) substrate 1 so that predetermined film thickness can be obtained.

Then, a film 6 made of a polycrystalline silicon based material containing at least one type of impurity is provided by covering a surface of the HfSiON film 5. This film 6 is provided as a gate electrode described later. In the present embodiment, a polysilicon (poly-Si) film is provided as a film made of a polycrystalline silicon based material. Specifically, by using the CVD technique, the polysilicon film 6 is formed on the surface of the HfSiON film 5 so that predetermined film thickness is obtained. At this time, in order to restrict or reduce the flat band shift described in the Background of the Invention section, a substance (element) for restricting the impurities contained in the polysilicon film 6 from moving from the inside of the polysilicon film 6 to the inside of the HfSiON film 5 is provided inside of the polysilicon film 6. However, excessive restriction of the dispersing of the impurities in the polysilicon film 6 becomes disadvantageous in view of depletion of a gate electrode. Therefore, it is preferable to maldistribute substances for restricting dispersion of impurities from the inside to the outside of the polysilicon film 6, in the vicinity of an interface between the HfSiON film 5 and the polysilicon film 6.

As described later, arsenic (As) that is an n-type impurity is doped at the inside of the polysilicon film 6 in a post-process. According to the latest testing, it has been verified that a flat band shift is caused by impurities dispersed into a gate insulating film, the impurities being boron (B), arsenic (As) and the like contained in a gate electrode made of a polycrystalline based material. In addition, it has been found that in the case where a gate insulating film is formed of a metal oxide based high relative dielectric constant insulating film, a flat band shift occurs due to a metal element contained in the gate insulating film dispersed into a gate electrode. Further, it has been found that in the case where a gate insulating film is formed of a metal oxide based high relative dielectric constant insulating film and a gate electrode is made of a polycrystalline silicon based material, a defect such as an oxygen loss occurs in an interface between the gate insulating film and the gate electrode. As a result, it has been found that a junction failure between the gate insulating film and the gate electrode occurs and that a flat band shift occurs.

Therefore, in the present embodiment, prior to doping As into the polysilicon film 6, a substance for restricting As contained in the polysilicon film 6 from moving from the inside of the polysilicon film 6 to the inside of the HfSiON film 5 is provided in the vicinity of an interface relevant to the HfSiON film 5 of the polysilicon film 6. According to the testing carried out by the Inventor, it was found that the movement (dispersion) of As from the inside of the polysilicon film 6 can be restricted by introducing carbon (C) into the polysilicon film 6, for example. Thus, in the present embodiment, C is introduced into the vicinity of the interface relevant to the HfSiON film 5 of the polysilicon film 6.

Specifically, an MOCVD gas made of a substance containing C such as methane gas (CH₄), propane gas (C₃H₈), or methanol gas (CH₃OH), for example is incorporated into a CVD gas (raw material gas) for forming the polysilicon film 6 at the initial stage of the film forming process of the polysilicon film 6. In this manner, as shown in FIG. 2, while a polysilicon layer (C-doped polysilicon layer) 6a containing C in the order of 10¹⁸ cm⁻³ to 10¹⁹ cm⁻³ is intensively formed in the vicinity of the interface relevant to the HfSiON film 5 of the polysilicon film 6, the polysilicon film 6 can be formed on the surface of the HfSiON film 5. The formed polysilicon film 6 is formed as a two-layered structure in which a lower layer portion coming into contact with the HfSiON film 5 is a C-doped polysilicon layer 6a and an upper layer portion which does not come into contact with the HfSiON film 5 is a substantially pure polysilicon layer 6b.

In the C-doped polysilicon layer 6a, as its thickness increases, C contained therein easily disperses into the whole polysilicon film 6, and its dispersion speed increases. That is, as the film thickness of the C-doped polysilicon layer 6a increases, the dispersion of As in the polysilicon film 6 is easily restricted. However, as described previously, if the dispersion of As in the polysilicon film 6 is excessively restricted, the characteristics of a gate electrode lowers. Therefore, it is preferable that the thickness of the C-doped polysilicon film 6a be smaller. Specifically, it is preferable that the C-doped polysilicon layer 6a be formed to be smaller than the polysilicon layer 6b in thickness. More specifically, it is preferable that the C-doped polysilicon layer 6a be set to be equal to or smaller than about 2 nm in thickness.

Next, as shown in FIG. 3, the HfSiON film 5 and the polysilicon film 6 are molded in their desired shapes, respectively, by using a general lithography technique and an RIE technique or the like, and a gate insulating film 5 and a gate electrode 6 are formed. Then, in accordance with the ion implantation technique (ion implanting technique), As that is an n-type impurity (dopant) is introduced into the gate electrode 6. At this time, As is also introduced into the surface layer portion of the p-well 4.

Specifically, As of about 1×10¹⁵ cm⁻² is ion-implanted with acceleration energy (implantation energy) of about 10 KeV into the polysilicon layer 6b of the gate electrode 6 and into the surface layer portion of the p-well 4. Then, for example, in accordance with a Rapid Thermal Anneal (RTA) technique, anneal processing is applied for about 5 seconds at about 900° C. to the As-implanted gate electrode 6 and p-well 4. In this manner, As is dispersed substantially uniformly and is activated into the polysilicon layer 6b of the gate electrode 6 and into the surface layer portion of the p-well 4. In addition, an attempt is made to recover damage due to implantation of As into the polysilicon layer 6b and into the surface layer portion of the p-well 4.

As described previously, among the gate electrode 6, the C-doped polysilicon layer 6a is provided in the vicinity of the interface relevant to the gate insulating film 5. Thus, As contained in the polysilicon layer 6b cannot be moved (dispersed) from the inside of the polysilicon layer 6b to the inside of the gate insulating film 5. That is, among the whole gate electrode 6 made of the C-doped polysilicon layer 6a and the polysilicon layer 6b, an As maldistribution coefficient increases in the polysilicon layer 6b. As a result, C is maldistributed in the vicinity of the interface relevant to the gate insulating film 5 and As disperses substantially uniformly only inside of the polysilicon layer 6b. In addition, a gate electrode 6 is obtained, the gate electrode having a component profile in which As does not disperse through the gate insulating film 5. In addition, an extension region (shallow junction region) 7 is formed in the surface layer portion of the p-well 4, the extension region serving as an electrical connection portion between a dispersion region of each of a source and a drain described later and a channel region which is not shown.

Then, a gate side wall film 8 is formed by using a general etch back technique. Then, in accordance with the ion implantation technique (ion implanting technique), phosphor (P) that is another n-type impurity (dopant) is implanted into the surface layer portion of the p-well 4 in which the extension region 7 has been formed. Specifically, P of about 5×10¹⁵ cm⁻² is ion-planted into the surface layer portion of the p-well 4 on which the extension region 7 has been formed. Then, for example, in accordance with a spike anneal technique, anneal processing is applied to the surface layer portion of the P-implanted p-well 4. In this manner, in the surface layer portion of the p-well 4, P is dispersed substantially uniformly and activated up to a position which is deeper than the extension region 7. In addition, an attempt is made to recover damage of the surface layer portion of the p-well 4 due to the implantation of P. As a result, as shown in FIG. 3, a contact region (deep junction region) 10 serving as dispersion regions 10a and 10b of each of the source and drain is substantially integrated with the extension region 7, and the integrated region is formed in the surface layer region of the p-well 4. That is, the source dispersion region 10a and the drain dispersion region 10b made of an LDD (Lightly Doped Drain) structure are formed in the transistor forming region 2 of the surface layer portion of the Si (100) substrate 1. Then, although illustration and a detailed description are omitted here, a general saliciding process or the like is carried out.

Then, as shown in FIG. 3, an interlayer insulating film 11 made of a SiO₂ or the like is provided on the surface 1a of the Si (100) substrate 1 by covering the gate insulating film 5, the gate electrode 6, the source dispersion region 10a, and the drain dispersion region 10b or the like provided in the transistor forming region 2 of the surface layer portion of the Si (100) substrate 1. Then, two contact plugs 12 made of copper (Cu) are provided in the interlayer insulating film 11, for example, each of which is brought into electrical contact with each one of the source dispersion region 10a and the drain dispersion region 10b. Then, two wires 13 made of Cu are provided on a surface of the interlayer insulating film 11 similarly, each of which is brought into contact with each of the contact plugs 12.

In accordance with the foregoing process, as shown in FIG. 3, MOSFET 14 made of a desired structure is provided in the transistor forming region 2 of the surface layer portion of the Si (100) substrate 1. That is, MOSFET 14 comprising the gate insulating film 5 made of the HfSiON film and the gate electrode 6 of two-layer structure made of the C-doped polysilicon layer 6a and the pure polysilicon layer 6b is provided in the transistor forming region 2 of the surface layer portion of the Si (100) substrate 1. In general, while a barrier metal film is provided by covering the surfaces of the contact plugs 12 and wires 13, descriptions of these elements are omitted in the present embodiment, and illustrations thereof are omitted in FIG. 3.

Further, through a predetermined process, a semiconductor device 15 according to the present embodiment is obtained, the semiconductor device comprising a desired transistor structure shown in FIG. 3. That is, the semiconductor device 15 is obtained, the device comprising a transistor structure in which the MOSFET 14 made of the previously described structure is provided in the transistor forming region 2 of the surface layer portion of the Si (100) substrate 1.

Now, with reference to FIGS. 4 and 5, a description will be given with respect to a measurement testing and a measurement result of C concentration profile in the vicinity of the gate electrode 6 along the film thickness direction (depth direction) of the gate electrode 6 of the MOSFET 14 which the Inventor carried out. FIG. 4 is an enlarged view showing the vicinity of the gate electrode 6 of the MOSFET 14. First, prior to starting testing, as shown in FIG. 4, a top face (surface) of the gate electrode 6 was defined as 0, and this depth was defined as a reference position (origin) for measuring a profile of C concentration. Under such setting, as indicated by the solid lined arrow in FIG. 4, the C-concentration profile in the vicinity of the gate electrode 6 along the depth direction from the surface of the gate electrode 6 was measured from the top face of the gate electrode 6 toward the inside (P-well 4) of the Si (100) substrate 1. The measurement result is shown in FIG. 5.

As shown in FIG. 5, among the gate electrode (polysilicon film) 6, the C-concentration is almost 0 in the pure polysilicon layer 6b that is the upper layer portion of the electrode. That is, it is evident that C hardly exists in the pure polysilicon layer 6b. However, the C-concentration rapidly increases immediately after Depth has entered the inside of the C-doped polysilicon layer 6a that is the lower layer portion of the gate electrode 6 through the pure polysilicon layer 6b. That is, among the gate electrode 6, it is evident that C is intensively maldistributed in the C-doped polysilicon layer 6a. Then, the C-concentration becomes 0 immediately after Depth has entered the inside of the gate insulating film (HfSiON film) 5 through the C-doped polysilicon layer 6a. That is, it is evident that C does not disperse (move) from the inside of the C-doped polysilicon layer 6a to the inside of the gate insulating film 5. In addition, according to another testing which the Inventor carried out, it was found that such a C-concentration profile can be obtained similarly in the case where the gate electrode 6 is formed by using a polysilicon germanium (poly-SiGe) film as well as in the case where the gate electrode 6 is formed by using the polysilicon film.

Now, with reference to FIGS. 6 and 7, a description will be given with respect to a measurement test and a measurement result of capacitor characteristics, of the MOSFET 14 and MOSFET according to a modified example thereof, and MOSFET according to Comparative Example relevant thereto, which the Inventor carried out. However, a detailed description and illustration are omitted with respect to each one of the MOSFET according to the modified example of the MOSFET 14 and the MOSFET according to Comparative

### EXAMPLE

First, four graphs depicted in FIG. 6 are provided as graphs depicting capacitor characteristics of the MOSFET in which C has been implanted in all the gate electrodes. From among these four graphs, graphs plotted by using an open rectangle and an open triangle are provided as graphs depicting capacitor characteristics of MOSFET according to the background technique as Comparative Example relevant to the MOSFET 14. Now, a specific description will be given below.

From among the four graphs shown in FIG. 6, a graph plotted by using a solid rectangle is provided as a graph depicting capacitor characteristics of the MOSFET 14. In contrast, a graph plotted by using an open rectangle in FIG. 6 is provided as a graph depicting capacitor characteristics of MOSFET according to Comparative Example 1 relevant to the MOSFET 14. This MOSFET according to Comparative Example 1 is provided as MOSFET in which only a gate insulating film has been formed by using a SiO₂ film that is a general insulating film, in a structure similar to that of the MOSFET 14. As is clear from these two graphs, it is evident that capacitor characteristics of the MOSFET 14 shows tendency which is almost identical to those of the MOSFET according to Comparative Example 1. That is, it is evident that variation (flat band shift) of a flat band voltage (V_{fb}) of the MOSFET 14 is restricted or reduced to be almost equal to that of the MOSFET according to Comparative Example 1 when the gate insulating film has been formed of the SiO₂ film.

In addition, a graph plotted by using a solid triangle shown in FIG. 6 is provided as a graph depicting capacitor characteristic of the MOSFET according to the modified example of the MOSFET 14. This MOSFET according to the modified example of the MOSFET 14 is provided as MOSFET in which B being a p (p⁺) type impurity has been introduced into the gate electrode instead of As being n (n⁺) type impurity in a structure similar to that of the MOSFET 14. Therefore, this MOSFET according to the modified example of the MOSFET 14 is provided as the MOSFET according to another aspect of the present invention, as in the MOSFET 14. In contrast, a graph plotted by using an open triangle in FIG. 6 is provided as a graph showing capacitor characteristics of MOSFET according to Comparative Example relevant to MOSFET according to the modified example of the MOSFET 14. In the following description, the MOSFET according to Comparative Example relevant to the MOSFET according to the modified example of the MOSFET 14 is referred to as MOSFET according to Comparative Example 2 relevant to the MOSFET 14. This MOSFET according to Comparative Example 2 is provided as MOSFET in which only a gate insulating film has been formed of a SiO₂ film in a structure similar to that of the MOSFET according to the modified example of the MOSFET 14.

As is clear from these two graphs, it is evident that capacitor characteristics of the MOSFET according to the modified example of the MOSFET 14 shows tendency which is almost identical to those of the MOSFET according to Comparative Example 2. That is, in the MOSFET according to the modified example of the MOSFET 14 as well, as in the MOSFET 14, it is evident that a flat band shift (V_{fb} shift) is restricted or reduced to be almost equal to that of the MOSFET according to Comparative Example 2 when the gate insulating film has been formed of the SiO₂ film.

Four graphs shown in FIG. 7 are provided as graphs depicting capacitor characteristics of MOSFET in which C is not implanted into all the gate electrodes. That is, the four graphs shown in FIG. 7 are provided as graphs depicting capacitor characteristics of the MOSFET according to Comparative Example relevant to the MOSFET 14. Now, a specific description will be given below.

Among the four graphs shown in FIG. 7, a graph plotted by using a solid rectangle is provided as a graph depicting capacitor characteristics of MOSFET in which C is not implanted in the gate electrode in a structure similar to the MOSFET 14. In the following description, the MOSFET in which C is not implanted in the gate electrode in a structure similar to that of the MOSFET 14 is referred to as MOSFET according to Comparative Example 3 relevant to the MOSFET 14. In contrast, a graph plotted by using an open rectangle in FIG. 7 is provided as a graph showing capacitor characteristics of MOSFET in which only the gate insulating film has been formed by using the SiO₂ film in a structure similar to that of the MOSFET according to Comparative Example. In the following description, the MOSFET in which only the gate insulating film has been formed by using the SiO₂ film in a structure similar to that of the MOSFET according to Comparative Example 3 is referred to as MOSFET according to Comparative Example 4 relevant to the MOSFET 14.

As is clear from these two graphs, it is evident that capacitor characteristics of the MOSFET according to Comparative Example 3 is greatly different from those of the MOSFET according to Comparative Example 4. Specifically, it is evident that the MOSFET according to Comparative Example 3 greatly varies in a direction a flat band voltage (V_{fb}) increases, with respect to the MOSFET according to Comparative Example 4 in which the gate insulating film has been formed of the SiO₂, as indicated by the solid lined arrow in FIG. 7. That is, it is evident a flat band shift in a positive direction which is greater than that of the MOSFET according to Comparative Example 4 occurs in the MOSFET according to Comparative Example 3.

In addition, a graph plotted by using a solid triangle in FIG. 7 is provided as a graph depicting capacitor characteristics of MOSFET according to another Comparative Example relevant to the MOSFET according to the modified example of the MOSFET 14 described previously. In the following description, the MOSFET according to another Comparative Example relevant to the MOSFET according to the modified example of the MOSFET 14 is referred to as MOSFET according to Comparative Example 5 relevant to the MOSFET 14. A graph relevant to this MOSFET according to Comparative Example 5 is provided as a graph depicting capacitor characteristics of MOSFET in which C is not implanted in the gate electrode in a structure similar to that of the MOSFET according to the modified example of the MOSFET 14. In contrast, a graph plotted by using an open triangle in FIG. 7 is provided as a graph depicting capacitor characteristics of MOSFET in which only the gate insulating film has been formed by using the SiO₂ film in a structure similar to that of the MOSFET according to Comparative Example 5. In the following description, the MOSFET in which only the gate insulating film has been formed by using the SiO₂ film in a structure similar to that of the MOSFET according to Comparative Example 5 is referred to as MOSFET according to Comparative Example 6 relevant to the MOSFET 14.

As is clear from these two graphs, it is evident that capacitor characteristics of the MOSFET according to Comparative Example 5 is greatly different from those of the MOSFET according to Comparative Example 6. Specifically, it is evident that the MOSFET according to Comparative Example 5 greatly varies in a direction in which a flat band voltage (V_{fb}) decreases, with respect to the MOSFET according to Comparative Example 6 in which the gate insulating film has been formed of the SiO₂ film, as indicated by a dashed lined arrow in FIG. 7. That is, it is evident that a flat band shift in a negative direction greater than that of the MOSFET according to Comparative Example 6 occurs with the MOSFET according to Comparative Example 5.

Further, as can be seen from comparison and study of each graph in FIGS. 6 and 7, there is almost a coincidence between the graph according to Comparative Example 1 and that according to Comparative Example 4. Similarly, it is evident that there is almost a coincidence between the graph according to Comparative Example 2 and that according to Comparative Example 6. That is, in the case where the gate electrode has been formed of a polysilicon film and the gate insulating film has been formed of the SiO₂ film, it is evident that capacitor characteristics of MOSFET hardly changes regardless of implantation of C into the gate electrode, and regardless of types or electrical conducting types of impurity implanted in the gate electrode.

Further, when graphs shown in FIGS. 6 and 7 are compared and studied in more detail, based on these results, the following matter is evident. In MOSFET in which a gate electrode is formed of a polysilicon film and a gate insulating film is formed of an HfSiON film, C is maldistributed in the vicinity of an interface relevant to a gate insulating film of a gate electrode, whereby regardless of types or electrically conductive types of impurities implanted in the gate electrode, a flat band shift can be restricted or reduced to be almost equal to that of the MOSFET in which the gate electrode is formed of the polysilicon film and the gate insulating film has been formed of the SiO₂ film. That is, in the MOSFET 14 according to the present embodiment or MOSFET made of a structure similar to that of the MOSFET 14, a C-doped layer is provided in the vicinity of an interface relevant to the gate insulating film of the gate electrode, whereby flat band voltage characteristics closer to ideal flat band voltage characteristics can be achieved as compared with a case in which no C-doped layer is provided, regardless of types of NMOS and PMOS. Finally, substantially ideal flat band voltage characteristics can be achieved in CMOSFET (CMISFET) as well formed by combining NMOSFET and PMOSFET made of a structure similar to that of the MOSFET 14 according to the present embodiment.

As has been described above, in this first embodiment, in NMOSFET (MIS transistor) 14 in which the gate insulating film 5 is made of the HfSiON film and the gate electrode 6 is made of the polysilicon film, a layer 6a doped with C for restricting entry of As contained in the gate electrode 6 into the gate insulating film 5 is formed in the vicinity of an interface relevant to the gate insulating film 5 of the gate electrode 6. In this manner, a flat band shift that occurs in the NMOSFET 14 can be restricted or reduced. As a result, a danger that it becomes difficult to control a threshold voltage of the NMOSFET 14 by a flat band shift can be restricted or reduced. In addition, a danger that an operation of the semiconductor device 15 comprising the NMOSFET 14 is made unstable due to a flat band shift is restricted or reduced, and operation can be stabilized. Therefore, in the semiconductor device 15, a failure rate caused by a flat band shift is restricted or reduced, and the yield is improved. In addition, in the NMOSFET 14 made of the previously described structure, there is almost no danger that depletion of the gate electrode 6 occurs.

In this manner, in the semiconductor device 15, a danger that its reliability, performance, and quality or the like are degraded is restricted or reduced, and productivity is improved. In addition, according to the present embodiment, the NMOSFET 14 and semiconductor device 15 having the previously described characteristics can be manufactured more efficiently and easily in accordance with a general semiconductor device manufacturing method (manufacturing process) without developing a special manufacturing method or undergoing a special manufacturing process.

Although not shown, as in the NMOSFET 14 according to the present embodiment, there has been conventionally proposed a large number of MOSFETs (MISFETs) in which a gate insulating film is formed of a high relative dielectric constant insulating film (high-k film) and a gate electrode is formed of a film made of a polysilicon based material. In addition, in the MOSFET made of such a structure, there has been proposed some techniques of introducing into a gate electrode a substance (element) other than general impurities (dopant) introduced into the gate electrode. However, most of these conventional techniques have been made in order to improve heat resistance of the gate electrode and to restrict the dopant contained in the gate electrode (polysilicon electrode) from dispersing through an Si substrate. In particular, with respect to the latter case, the relevant techniques are based on an idea that a dispersion coefficient of the dopant contained in a high relative dielectric constant insulating film is reduced in the case where the dopant contained in the gate electrode enters the high relative dielectric constant insulating film, and entry of dopant into the high relative dielectric constant insulating film is permitted.

In contrast, the NMOSFET 14 and semiconductor device 15 according to the present embodiment, as described previously, have been made based on an idea that As contained in the gate electrode (polysilicon film) 6 is prevented from entering the gate insulating film (HfSiON film) 5. Therefore, the technique according to the present embodiment is completely different from the previously described conventional technique in their technical idea.

According to so called TSB (Thin Surface Barrier) internal theoretical calculation, it is evident that a flat band shift (V_{fb} shift) in the high relative dielectric constant gate insulating film/polysilicon gate electrode structure occurs due to a composite defect among a variety of substances (elements) including high relative dielectric constant metal (high-k metal) that exists in the vicinity of an interface between the high relative dielectric constant gate insulating film and the polysilicon gate electrode. For example, as in the MOSFET 14 according to the present embodiment, it is evident that a V_{fb} shift in MOSFET in which the gate insulating film is made of the HfSiON film and the gate electrode is made of the polysilicon film occurs due to a composite defect between Hf (high-k metal), oxygen (O), and Si contained in the HfSiO film and the dopant contained in the polysilicon film, the above contained elements existing in the vicinity of the interface between the HfSiON film and the polysilicon film. Therefore, in order to restrict or reduce the V_{fb} shift in the MOSFET having the HfSiO film/polysilicon film structure, for example, the dopant contained in the polysilicon film may be prevented from entering the HfSiON film. In order to achieve the above restriction or reduction, a portion of the polysilicon gate electrode coming into contact with the high relative dielectric constant gate insulating film may be set in a structure capable of restricting the dopant contained in the polysilicon gate electrode from dispersing through the inside of the high relative dielectric constant gate insulating film. Ideally, it is preferable to intensively introduce a substance (element) capable of restricting the dopant contained in the polysilicon gate electrode from dispersing through the inside of the high relative dielectric constant gate insulating film only on the interface relevant to the high relative dielectric constant gate insulating film of the polysilicon gate electrode.

As described previously, in the MOSFET 14 according to the present embodiment, C, being an element for modulating a dispersion coefficient of As in the polysilicon gate electrode 6, is introduced into the polysilicon gate electrode 6 on the interface between the high relative dielectric constant gate insulating film 5 and the polysilicon gate electrode 6. In this manner, As is maldistributed only in the polysilicon gate electrode 6, and As is prevented from entering from the inside of the polysilicon gate electrode 6 to the inside of the high relative dielectric constant gate insulating film 5. As a result, in the MOSFET 14 according to the present embodiment, while restricting depletion of the polysilicon gate electrode 6, a V_{fb} shift that occurs commonly with general MOSFET having the high relative dielectric constant gate insulating film/polysilicon gate electrode structure can be restricted or reduced to almost equal to a V_{fb} shift that occurs with the MOSFET in which the gate insulating film is made of the SiO₂ film and the gate electrode is made of the polysilicon based film.

### Second Embodiment

Now, a second embodiment according to the present invention will be described while illustration thereof is omitted. The same constituent elements as those according to the first embodiment described previously are designated by the same reference numerals. A detailed description thereof is omitted here.

In the present embodiment, nitrogen (N) is introduced into a gate electrode instead of C used in the first embodiment, as a substance for preventing the impurities contained in the gate electrode made of a polysilicon based film from dispersing in a gate insulating film made of a high relative dielectric constant insulating film. A specific description will be given below.

First, in accordance with the processes similar to those according to the first embodiment, from a first process up to a process for forming a gate insulating film 5 made of an HfSiON film are executed. Then, an MOCVD gas made of a substance containing N such as ammonia (NH₃), nitrogen oxide (NO), or di-nitrogen oxide (N₂O), for example, is incorporated into a raw material gas of a polysilicon film at the initial stage of a process for forming a polysilicon film serving as a gate electrode. In this manner, a polysilicon layer (N-doped polysilicon layer) containing N in the order of 1018 cm⁻³ to 1019 cm⁻³ is intensively formed in the vicinity of an interface relevant to an HfSiON film 5 of a polysilicon film, and the polysilicon film is formed on a surface of the HfSiON film 5. The resulting polysilicon film is formed in a two-layered structure in which a lower layer portion which comes into contact with the HfSiON film 5 is an N-doped polysilicon layer and an upper layer portion which does not come into contact with the HfSiON film 5 is a polysilicon layer 6b. As is the C-doped polysilicon layer 6a according to the first embodiment, it is preferable that the N-doped polysilicon layer be formed to be thin. Specifically, it is preferable that the N-doped polysilicon layer be set to be equal to or smaller than 2 nm in thickness.

Then, through the processes similar to those in the first embodiment, there is obtained a semiconductor device according to the present embodiment, comprising MOSFET in which a gate electrode is made of a two-layered structure having an N-doped polysilicon layer and a substantially pure polysilicon layer 6b.

As has been described above, in the second embodiment, N capable of preventing the impurities contained in a gate electrode from dispersing through the inside of a gate insulating film made of a high relative dielectric constant insulating film, as is C, is maldistributed in the vicinity of an interface relevant to a gate insulating film (HfSiON film 5) of a gate electrode (polysilicon film), so that an advantageous effect similar to that according to the first embodiment described previously can be attained.

### Third Embodiment

Now, a third embodiment according to the present invention will be described while illustration thereof is omitted. The same constituent elements as those according to the first embodiment are designated by the same reference numerals. A detailed description thereof is omitted here.

In the present embodiment, the impurities contained in a gate electrode made of a polysilicon based film can be prevented from dispersing through the inside of a gate insulating film made of a high relative dielectric constant insulating film. In addition, a substance for restricting the lowering of coincidence in an interface between the gate electrode and the gate insulating film is introduced into the gate electrode. A specific description will be given below.

First, in accordance with the processes similar to those according to the first embodiment, from a first process up to a process for forming a gate insulating film 5 made of an HfSiON film are executed. Then, at the initial stage of the process for forming the polysilicon film serving as a gate electrode, a polysilicon film is formed while a partial pressure of oxygen (O) contained in an atmosphere is set to be higher than usual. In this manner, while a polysilicon layer (O-doped polysilicon layer) containing 0 in the order of 10¹⁸ cm⁻³ to 10¹⁹ cm⁻³ is intensively formed in the vicinity of an interface relevant to an HfSiO film 5 of a polysilicon film, the polysilicon film is formed on a surface of the HfSiON film 5. The resulting polysilicon film is formed in a two-layered structure in which a lower layer portion which comes into contact with the HfSiON film 5 is an O-doped polysilicon layer and an upper layer portion which does not come into contact with the HfSiON film 5 is a polysilicon layer 6b. As is the C-doped polysilicon layer 6a according to the first embodiment and the N-doped polysilicon layer according to the second embodiment, it is preferable that the O-doped polysilicon layer be also formed to be small in thickness. Specifically, it is preferable that the O-doped polysilicon layer be also set to be equal to or smaller than about 2 nm in thickness.

Then, through the processes similar to those according to the first embodiment, there is obtained a semiconductor device according to the present embodiment, comprising MOSFET in which a gate electrode is made of a two-layered structure having an O-doped polysilicon layer and a substantially pure polysilicon layer 6b.

It is known that, when a gate insulating film is formed of a high relative dielectric constant insulating film made of a metal oxide and a gate electrode is formed of a film made of a polysilicon based material, a defect such as an oxygen loss occurs in an interface between the gate electrode and the gate insulating film. In addition, it is known that, if a defect such as an oxygen loss occurs in an interface between the gate electrode and the gate insulating film, a junction failure occurs with the gate insulating film and the gate electrode in the interface therebetween. Further, it is known that, if a junction failure occurs with the gate insulating film and the gate electrode in the interface therebetween, a MOSFET flat band shift increases as is the case with entry of the impurities contained in the gate electrode into the gate insulating film.

In MOSFET according to the present embodiment, as described previously, O is introduced into a polysilicon gate electrode. In addition, according to testing which the Inventor carried out, it is known that O introduced into the polysilicon film can prevent the impurities contained in the gate electrode made of the polysilicon based film from dispersing through the inside of the gate insulating film made of a high relative dielectric constant insulating film and that an oxygen loss prone to occur in the interface between the gate electrode and the gate insulating film can be restricted or reduced. Therefore, in the MOSFET according to the present embodiment, a danger that a defect such as an oxygen loss occurs in the interface between the polysilicon gate electrode and the high relative dielectric constant gate insulating film 5 is restricted or reduced. That is, in the MOSFET according to the present embodiment, the lowering of the coincidence in the interface between the polysilicon gate electrode and the high relative dielectric constant gate insulating film 5 is restricted or reduced.

As has been described above, according to the third embodiment, there can be attained an advantageous effect similar to those of the first and second embodiments described previously. In addition, in the MOSFET according to the present embodiment, the lowering of the coincidence in the interface between the polysilicon gate electrode and the high relative dielectric constant gate insulating film 5 is restricted or reduced, and a junction state between the polysilicon gate electrode and the high relative dielectric constant gate insulating film 5 is improved. In addition, in the MOSFET according to the present embodiment, there is almost no danger that the impurities contained in the polysilicon gate electrode enters the high relative dielectric constant gate insulating film 5. Therefore, the MOSFET according to the present embodiment and a semiconductor device comprising this MOSFET are improved more remarkably in reliability, performance, and quality or the like and are improved more remarkably in productivity, as compared with the MOSFET 14 and semiconductor device 15 according to the first embodiment and those according to the second embodiment. Further, according to the present embodiment, the MOSFET and semiconductor device comprising the O-doped polysilicon layer described previously can be manufactured more efficiently and easily in accordance with a general semiconductor device manufacturing method (manufacturing process) without developing a specific manufacturing method or undergoing a specific manufacturing process.

### Fourth Embodiment

Now, a fourth embodiment according to the present embodiment will be described while illustration thereof is omitted. The same constituent elements as those according to the first embodiment described previously are designated by the same reference numerals. A detailed description thereof is omitted here.

In the present embodiment, the impurities contained in a gate electrode made of a polysilicon based film can be prevented from dispersing through the inside of a gate insulating film made of a high relative dielectric constant insulating film. In addition, a substance capable of restricting the dispersion of metal element contained in the gate insulating film into the gate electrode is introduced into the gate electrode. A specific description will be given below.

First, in accordance with the processes similar to those according to the first embodiment, from a first process to a process for forming a gate insulating film 5 made of an HfSiON film are executed. Then, an MOCVD gas made of a substance containing a metal element other than Hf contained in the gate insulating film 5 that is a high relative dielectric constant material (high-k material) is incorporated into a raw material gas of a polysilicon film at the initial stage of a process for forming a polysilicon film serving as a gate electrode. For example, an MOCVD gas made of a substance including aluminum (Al) such as TMA (Al (CH₃)₃), for example, is incorporated into the raw material gas of the polysilicon film. After the TMA gas has been supplied for a predetermined period of time, the supply of the TMA gas is stopped and the current gas incorporated into the raw material gas of the polysilicon film is changed to another gas. For example, as in the second embodiment described previously, an MOCVD gas made of a substance containing N such as ammonia (NH₃) is incorporated into the raw material gas of the polysilicon film instead of the TMA gas.

In accordance with such a process, while a polysilicon layer (Al/N-doped polysilicon layer) containing Al and N in the order of 10¹⁸ cm⁻³ to 10¹⁹ cm⁻³ respectively is intensively formed in the vicinity of an interface relevant to the HfSiON film 5 of the polysilicon film, the polysilicon film is formed on a surface of the HfSiON film 5. The resulting polysilicon film is formed in a two-layered structure in which a lower layer portion coming into contact with the HfSiON film 5 is an Al/N-doped polysilicon layer and an upper layer portion which does not come into contact with the HfSiON film 5 is a substantially pure silicon layer 6b. As is the C-doped polysilicon layer 6a according to the first embodiment, the N-doped polysilicon layer according to the second embodiment, and the O-doped polysilicon layer according to the third embodiment, it is preferable that the Al/N-doped polysilicon layer be also formed to be small in thickness. Specifically, it is preferable that the Al/N-doped polysilicon layer be also set to be equal to or smaller than 2 nm in thickness.

Then, through the processes similar to those according to the first embodiment, there is obtained a semiconductor device according to the present embodiment, comprising MOSFET in which a gate electrode is made of a two-layered structure having an Al/N-doped polysilicon layer and a substantially pure polysilicon layer 6b.

It is known that, when a metal contained in a gate insulating film made of a high relative dielectric constant insulating film dispersed through the inside of a gate electrode, a MOSFET flat band shift increases as is the case with entry of the impurities contained in the gate electrode into the gate insulating film. In the MOSFET according to the present embodiment, as described previously, Al and N are introduced into the polysilicon gate electrode. Then, according to the testing that the Inventor carried out, it is known that Al introduced into the polysilicon film can prevent the impurities contained in the gate electrode made of the polysilicon based film from dispersing through the inside of the gate insulating film made of the high relative dielectric constant insulating film and that the metal contained in the gate insulating film can be prevented from dispersing through the inside of the gate electrode. In addition, Al is easily oxidized as compared with Hf and a layer containing Al obtained as oxide is obtained as a stable insulating film. Thus, it becomes difficult for Hf contained in the high relative dielectric constant gate insulating film 5 to release O from the film, and a danger that an oxygen loss occurs in the vicinity of an interface between the polysilicon gate electrode and the high relative dielectric constant gate insulating film 5 can also be restricted or reduced.

As has been described above, according to the fourth embodiment, there can be attained an advantageous effect similar to those according to the first to third embodiments described previously. In addition, in the MOSFET according to the present embodiment, Al and N are introduced into the polysilicon gate electrode. Thus, there is almost no danger that the impurities contained in the polysilicon gate electrode enters the high relative dielectric constant gate insulating film 5 and there is almost no danger that Hf contained in the high relative dielectric constant gate insulating film 5 enters the polysilicon gate electrode. In addition, a danger that a oxygen loss occurs in the vicinity of an interface between the polysilicon gate electrode and the high relative dielectric constant gate insulating film 5 is also restricted or reduced. Therefore, MOSFET and a semiconductor device comprising the MOSFET according to the present embodiment, as in the MOSFET and semiconductor device according to the third embodiment, are improved more remarkably in reliability, performance, and quality or the like and are improved more remarkably in productivity, as compared with the MOSFET 14 and semiconductor 15 according to the first embodiment and the MOSFET and semiconductor device according to the second embodiment. In addition, according to the present embodiment, the MOSFET and semiconductor device comprising the Al/N-doped polysilicon layer described previously can be manufactured more efficiently and easily in accordance with a general semiconductor device manufacturing method (manufacturing process) without developing a special manufacturing method or undergoing a specific manufacturing process.

The semiconductor device and its relevant manufacturing method according to the present embodiment are not limited to the first to fourth embodiments described previously. These device and manufacturing method can be embodied by changing the constituent elements or part of the manufacturing process to a variety of settings or properly and adequately using a variety of settings in combination without departing from the spirit of the invention.

For example, a film made of a polycrystalline silicon based material serving as a gate electrode 6 is not limited to the above described polysilicon film 6. This gate electrode may be formed of a polysilicon germanium film (poly-SiGe film), for example.

In addition, an insulating film having a relative dielectric constant of 5 or more serving as a gate insulating film 5 is not limited to the HfSiON film 5 described previously. This gate insulating film may be formed of a high relative dielectric constant insulating film comprising Hf being a high relative dielectric constant metal element (high-k metal element), such as HfO₂ film and HfSiO film, for example.

In addition, a substance for preventing the impurities contained in a gate electrode made of a polysilicon based film from dispersing through the inside of a gate insulating film made of a high relative dielectric constant insulating film is not limited to C used in the first embodiment, N used in the second embodiment or the like. As such a substance, for example, boron nitride (BN) or the like, as a compound containing at least one of carbon (C) and nitrogen (N), can be used. In addition, a method for introducing a substance for preventing the impurities contained in the gate electrode from dispersing through the inside of the gate insulating film is not limited to the gas incorporating technique described previously. As another method for introducing a substance for preventing the impurities contained in the gate electrode from dispersing through the inside of the gate insulating film, for example, an ion implantation technique (ion implanting technique) or the like may be employed. According to these methods, the substance for preventing the impurities from dispersing can be doped within the range of 10¹⁸ cm⁻³ to 10¹⁹ cm⁻³, thereby restricting entry of the impurities into the gate insulating film without degradation of reliability due to excessive doping.

In addition, a substance for preventing the impurities contained in a gate electrode made of the polysilicon based film from dispersing through the inside of a gate insulating film made of a high relative dielectric constant insulating film, and restricting lowering of the coincidence in an interface between a gate electrode and a gate insulating film is not limited to O used in the third embodiment. Such a substance may be a substance having property similar to that of O.

Further, a substance for preventing the impurities contained in a gate electrode made of the polysilicon based film from dispersing through the inside of a gate insulating film made of a high relative dielectric constant insulating film, and restricting the dispersion of metal elements contained in the gate insulating film into the gate electrode is not limited to Al used in the fourth embodiment. As such a substance, a metal element other than Hf may be used, for example. Specifically, such substances include Al, Ti, W, Ta, Ru and the like.

By the above described settings, there can be obtained functions and advantageous effects similar to those of at least one of the first to fourth embodiments described previously. That is, even by the above described setting as well, a flat band shift, caused by MOSFET (MISFT) in which the gate insulating film 5 and the gate electrode 6 are composed of a high-k film 5 and a poly-Si film 6, can be restricted or reduced to substantially equal to that caused by the conventional MOSFET (MISFET) in which the gate insulating film and the gate electrode 6 are composed of a SiO₂ film/poly-Si film structure or a SiO₂ film/poly-SiGe film structure, while restricting depletion of the gate electrode 6.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor substrate having at least one pair of a source region and a drain region being formed at a surface layer portion thereof;
a gate insulating film being provided on a surface of the semiconductor substrate between the source region and the drain region and having a relative dielectric constant of 5 or more; and
a gate electrode being provided on a surface of the gate insulating film and made of a polycrystalline silicon based material containing at least one type of impurity, wherein a substance which restricts movement of the impurity from the polycrystalline silicon based material to the gate insulating film is provided in a vicinity of an interface to the gate insulating film.

2. The device according to claim 1, wherein
the gate insulating film is composed of a metal oxide; and
a substance which restricts movement of a metal element configuring the metal oxide from the gate insulating film to the gate electrode is further provided in the vicinity of the interface to the gate insulating film of the gate electrode.

3. The device according to claim 1, wherein
the gate insulating film is composed of a metal oxide; and
the substance which restricts movement of the impurity from the polycrystalline silicon based material to the gate insulating film further restricts lowering coincidence in the interface between the gate electrode and the gate insulating film.

4. The device according to claim 1, wherein
the gate electrode is formed in a two-layered structure;
a lower layer portion of the gate electrode coming into contact with the gate insulating film is made of a polycrystalline silicon based material to which the substance is doped; and
an upper layer portion of the gate electrode which does not come into contact with the gate insulating film is made of a polycrystalline silicon based material to which the substance is not doped.

5. The device according to claim 4, wherein the lower layer portion of the gate electrode is formed to be equal to or smaller than 2 nm in thickness.

6. The device according to claim 1, wherein the gate electrode is formed of polysilicon or polysilicon germanium.

7. The device according to claim 1, wherein the gate insulating film includes at least hafnium (Hf).

8. The device according to claim 1, wherein the gate insulating film is formed of any one of HfSiON, HfO₂, and HfSiO.

9. The device according to claim 1, wherein a material selected from the group consisting of carbon (C), nitrogen (N), and a compound including at least one of these is added to the gate electrode, as the substance which restricts movement of the impurity from the polycrystalline silicon based material to the gate insulating film.

10. The device according to claim 2, wherein a metal other than the metal element is added into the gate electrode, as the substance which restricts movement of the metal element from the gate insulating film to the gate electrode.

11. The device according to claim 10, wherein at least one of aluminum (Al), titanium (Ti), tungsten (W), tantalum (Ta), and ruthenium (Ru) is added to the gate electrode, as the metal other than the metal element.

12. The device according to claim 3, wherein at least one of oxygen (O) and a substance having property similar to that of oxygen is added to the gate electrode, as the substance which restricts lowering coincidence in the interface between the gate electrode and the gate insulating film.

13. The device according to claim 1, wherein
a silicon crystalline substrate is used as the semiconductor substrate; and
the gate insulating film and the gate electrode are provided on a (100) face of the silicon crystalline substrate.

14. A semiconductor device comprising:
a semiconductor substrate having at least one pair of a source region and a drain region being formed at a surface layer portion thereof;
a gate insulating film being provided on a surface of the semiconductor substrate between the source region and the drain region and having a relative dielectric constant of 5 or more; and
a gate electrode being provided on a surface of the gate insulating film and made of a polycrystalline silicon based material containing at least one type of impurity, wherein at least one of carbon (C), nitrogen (N), and oxygen (O) is maldistributed in a vicinity of an interface to the gate insulating film.

15. The device according to claim 14, wherein at least one of the carbon (C), the nitrogen (N), and the oxygen (O) is maldistributed in the vicinity of the interface to the gate insulating film of the gate electrode in the range of 10¹⁸ cm⁻³ to 10¹⁹ cm⁻³.

16. The device according to claim 14, wherein at
the gate insulating film is composed of a metal oxide; and
a metal other than a metal element which compose the metal oxide is further maldistributed in the vicinity of the interface to the gate insulating film of the gate electrode.

17. The device according to claim 16, wherein the metal other than the metal element which compose the metal oxide is at least one of aluminum (Al), titanium (Ti), tungsten (W), tantalum (Ta), and ruthenium (Ru).

18. A semiconductor device comprising:
a semiconductor substrate having at least one pair of a source region and a drain region being formed at a surface layer portion thereof;
a gate insulating film being provided on a surface of the semiconductor substrate between the source region and the drain region and having a relative dielectric constant of 5 or more; and
a gate electrode being provided on a surface of the gate insulating film and made of a polycrystalline silicon based material containing at least one type of impurity, wherein at least one of aluminum (Al), titanium (Ti), tungsten (W), tantalum (Ta), and ruthenium (Ru) is maldistributed in a vicinity of an interface to the gate insulating film.

19. The device according to claim 18, wherein the gate insulating film includes at least hafnium (Hf).

20. The device according to claim 18, wherein at least one of the aluminum (Al), the titanium (Ti), the tungsten (W), the tantalum (Ta), and the ruthenium (Ru) is maldistributed in the vicinity of the interface to the gate insulating film of the gate electrode in the range of 10¹⁸ cm⁻³ to 10¹⁹ cm⁻³.
